(19) United States
(12) Patent Application Publication
(10) Pub. No.: US 2003/0054636 A1
(43) Pub. Date: Mar. 20, 2003

(54) Method for manufacturing a semiconductor device and method for processing substrate

(75) Inventors: Masayuki Tsuneda, Tokyo (JP); Hideharu Itatani, Tokyo (JP); Atsushi Sano, Tokyo (JP)

Correspondence Address: MCGINN & GIBB, PLLC, 8321 OLD COURTHOUSE ROAD, SUITE 200, VIENNA, VA, 22182-3817, US

(73) Assignee: Hitachi Kokusai Electric Inc., Tokyo (JP)

(21) Appl. No.: 10/234,842

(22) Filed: Sep. 5, 2002

(30) Foreign Application Priority Data
Sep. 7, 2001 (JP) 2001-272219

(51) Int. Cl. H01L 21/44

(52) U.S. Cl. 438/681

(57) ABSTRACT

A method for manufacturing a semiconductor device and a method for processing a substrate are provided in which films containing Ru can be easily fabricated with good step coverage, reduced deposition delay times and hence good in-plane uniformity. The films containing Ru are deposited on a substrate by using a gas vaporized from Ru[CH₃COCHCO(CH₂)₃CH₃]₃ and an oxygen-containing gas at a deposition temperature of 250° C. to 305° C. and at a partial pressure of the oxygen-containing gas of 6.9 Pa or less.

### BACKGROUND OF THE INVENTION

1. Field of the Invention

The present invention relates to a method for manufacturing a semiconductor device and a method for processing a substrate so as to form films containing Ru on the substrate.

2. Description of the Related Art

Conventionally, SiN films or the like are used as capacitor materials forming memories. However, using SiN films as capacitor materials is disadvantageous in that the height of capacitors formed of SiN films becomes large and hence the power consumption of an entire chip including such capacitors is accordingly increased. Thus, it is thought that Ta₂O₅ or BST films having a dielectric constant higher than that of the SiN films are promising as capacitor materials. However, since BST films react with Si-based films (Poly-Si, HSG, etc.) of lower electrode materials, it is necessary to study an MIM (metal-insulator-metal) structure with its lower electrodes formed of metal films, instead of an MIS (metal-insulator-silicon) structure with its lower electrodes formed of Si-based films.

Films made of noble metals such as Pt, Ru, etc., are studied as such metal films, and among them, Ru films, which are relatively easy to process, are generally considered to be promising as next generation electrode materials. Incidentally, it has been reported that Ta₂O₅ films has a dielectric constant of about 25 in bulk, but the dielectric constant thereof goes up to 40-70 in case of an MIM structure using Ru films and Ta₂O₅ films. Accordingly, it is strongly demanded in the industries concerned to develop and put the combination of Ta₂O₅ films and Ru films, which can be handled comparatively easily, into practical or commercial use.

In order to cope with high integration of semiconductor devices, high film thickness uniformity and high step coverage (ability to cover steps) are required for electrode materials. In the formation of Ru films according to sputtering, excellent results are obtained in the uniformity and film quality, but it is difficult to form Ru films on the bottom surfaces of contact holes having an aspect ratio of about 10. Thus, it is necessary to develop a deposition method which is capable of providing satisfactory step coverage even in cases where the aspect ratio of contact holes is 10 or therearound, and hence it is important to establish a technique for forming Ru films according to CVD methods.

It is thought that bisethyl-cyclopentadienyl-ruthenium (Ru(C₂H₅C₅H₄)₂) can be used as a precursor (raw material) for the formation of Ru films according to CVD methods. When this precursor is used, the adhesion of the deposited Ru films with their underlayers, especially SiO₂ films, is poor in a deposition condition under which good step coverage can be obtained, so the Ru films thus deposited are easy to peel off from the underlayers. In addition, a delay time in the deposition is long and hence the deposition time also becomes long, as a result of which the cost of the precursor is increased and the throughput is reduced. Moreover, there might be generated differences between the portions in which the Ru films are able to easily adhere or attach to the underlayers and the portions in which it is rather difficult for the Ru films to adhere or attach to the underlayers, so that the in-plane uniformity of the film thickness, i.e., the uniformity in film thickness on the surface of the wafer, would be liable to be deteriorated.

### SUMMARY OF THE INVENTION

The present invention is intended to obviate the problems as referred to above, and has for its object to provide a method for manufacturing a semiconductor device and a method for processing a substrate in which films containing Ru can be easily formed with excellent step coverage, a short delay time in deposition and hence good in-plane uniformity of the film thickness.

In order to achieve the above object, according to one aspect of the present invention, there is provided a method for manufacturing a semiconductor device in which films containing Ru are deposited on a substrate by using a gas vaporized from Ru[CH₃COCHCO(CH₂)₃CH₃]₃ and an oxygen-containing gas at a deposition temperature of 250° C. to 305° C. and at a partial pressure of the oxygen-containing gas of 6.9 Pa or less.

Thus, it is possible to provide a method for manufacturing a semiconductor device in which films containing Ru can be easily fabricated with good step coverage, a reduced deposition delay time and hence good in-plane uniformity.

According to another aspect of the present invention, there is provided a method for processing a substrate in which films containing Ru are deposited on the substrate by using a gas vaporized from Ru[CH₃COCHCO(CH₂)₃CH₃]₃ and an oxygen-containing gas at a deposition temperature of 250° C. to 305° C. and at a partial pressure of the oxygen-containing gas of 6.9 Pa or less.

Accordingly, it is possible to provide a method for processing a substrate in which films containing Ru can be easily fabricated with good step coverage, a reduced deposition delay time and hence good in-plane uniformity.

According to a further aspect of the present invention, there is provided a method for manufacturing a semiconductor device in which films containing Ru are deposited on a silicon-based insulation film, a barrier metal or a capacitive insulation film by using a gas vaporized from Ru[CH₃COCHCO(CH₂)₃CH₃]₃.

Thus, it is possible to provide a method for manufacturing a semiconductor device in which films containing Ru can be easily fabricated with good step coverage, a reduced deposition delay and hence good in-plane uniformity.

The above and other objects, features and advantages of the present invention will become more readily apparent to those skilled in the art from the following detailed description of preferred embodiments of the present invention taken in conjunction with the accompanying drawings.

### DESCRIPTION OF THE DRAWINGS

FIG. 1 is a view for explaining one example of a thermal CVD apparatus which can be used by the present invention.

FIG. 2 is a view showing a comparison between the deposition delay times when depositions are made by using a Ru(EtCp)₂ gas and a Ru(OD)₃ gas, respectively, for an underlayer film made of (SiO₂).

FIG. 3 is a view explaining the relation among the flow rate of an oxygen-containing gas, the deposition temperature and the step coverage.

FIG. 4 is a view explaining the relation between the flow rate of the Ru(OD)3 gas and the step coverage.

FIG. 5 is a view explaining the relation between the partial pressure of oxygen and the step coverage.

FIG. 6 is a view explaining the relation between the flow rate of an oxygen gas and the step coverage.

FIGS. 7(a) and 7(b) are cross sectional views explaining the different states of the Ru films deposited on the surface of a hole prepared on the surface of a substrate.

FIG. 8 is a cross sectional view showing a part of a DRAM including ruthenium films or ruthenium oxide films formed by using the manufacturing method of the present invention.

### DESCRIPTION OF THE PREFERRED EMBODIMENTS

Now, preferred embodiments of the present invention will be described below in detail while referring to the accompanying drawings.

A method of manufacture according to the present invention is characterized in that a gas vaporized from Ru[CH₃COCHCO(CH₂)₃CH₃]₃ (tris-2,4-octanedionato-ruthenium, which is hereinafter abbreviated as Ru(OD)₃), which is used as a precursor forming films containing Ru (hereinafter simply referred to as Ru films), is supplied to a substrate together with a gas containing oxygen under a specific deposition condition thereby to form Ru films on the substrate.

The above-mentioned deposition condition is that the deposition temperature is in the range of 250° C. to 305° C. and that the oxygen-containing gas has a partial pressure of 6.9 Pa or less. If the Ru films are deposited under this deposition condition, step coverage can be controlled to be 80% or more. In addition, if the deposition temperature is in the range of 250° C. to 300° C., and if the partial pressure of the oxygen-containing gas is 6.9 Pa or less, step coverage can be controlled to be 90% or more. The flow rate of the oxygen-containing gas is preferably 50 sccm or less; the partial pressure of the Ru(OD)₃ gas is preferably 30 Pa or lower; and the flow rate of the Ru(OD)₃ gas is preferably 1 ccm or less. Moreover, the pressure in a reaction chamber is preferably higher than 66.5 Pa (0.5 Torr), and more preferably equal to or higher than 133 Pa (1 Torr) for example. When the pressure in the reaction chamber becomes equal to or less than 66.5 Pa (0.5 Torr), the step coverage tends to be deteriorated. Note that the oxygen-containing gas used in the present invention can be properly chosen from a variety of kinds of gases containing oxygen according to specific usage, but a typical example of the oxygen-containing gas is oxygen (O₂) itself.

Note that it is possible to form either a ruthenium film or a ruthenium oxide film by properly determining the above-mentioned deposition condition in accordance with a specific purpose. In addition, the thickness of the Ru films is in the range of 20-50 nm, for instance.

Moreover, other conditions can be properly set as in the well-known conventional CVD methods.

An underlayer film formed under the Ru films as necessary is not specifically limited in the present invention, but capacitive insulation films such as barrier metals (Ta₂05, BST), silicon-based insulation films (TiN, TiO₂, WN, TiAlN) such as SiO₂, Si₃N₄, etc., are enumerated for example as underlayer films. In the past, when films were deposited by using Ru(C₂H₅C₅H₄)₂ (bisethyl-cyclopentadienyl-ruthenium, which is hereinafter referred to as Ru(EtCp)₂), on these underlayer films, a deposition delay was generated. According to the present invention, however, such a deposition delay is hardly generated because of the use of a Ru(OD)₃ gas.

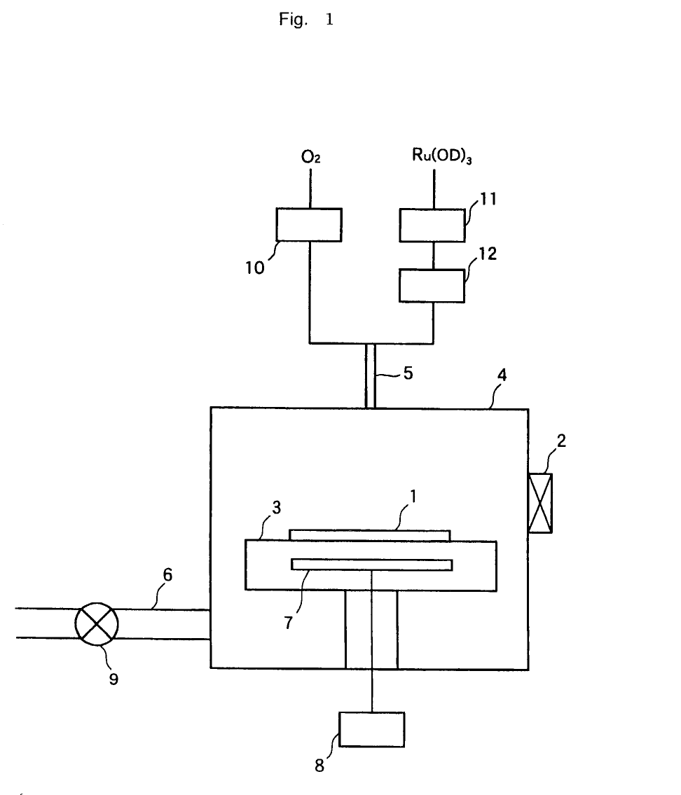

FIG. 1 is a view explaining one example of a thermal CVD apparatus which can be used in the present invention. In FIG. 1, a substrate 1 is disposed on a substrate holder 3 equipped with a heater 7 by means of a delivery robot (not shown) while passing through a gate valve 2. The heater 7 is caused to move upwardly to a prescribed position by means of a lift mechanism, and heats the substrate 1 to a desired temperature. Subsequently, after the pressure in a reaction chamber 4 becomes stabilized to a desired value, a Ru(OD)₃ gas and an oxygen-containing gas are introduced from a gas supply port 5 onto the substrate 1 and exhausted from a gas exhaust port 6, whereby films of Ru(OD)₃ are deposited on the substrate 1. Here, note that the temperature, the pressure, the flow rate of the oxygen gas and the flow rate of the Ru(OD)₃ gas in each process are controlled by means of a temperature control device 8, a pressure control device 9, a oxygen gas flow rate control device 10, and a Ru(OD)₃ flow rate control device 11, respectively. The Ru(OD)₃ is vaporized by a vaporizer 12. When the deposition is completed, the substrate 1 is carried out from the reaction chamber 4 by the delivery robot. In FIG. 1, the Ru(OD)₃ gas and the oxygen-containing gas are mixed with each other in piping before they are introduced in the reaction chamber 4, but they may instead be mixed with each other in the reaction chamber 4 without having previously been mixed in the piping. Moreover, although a cold wall furnace or reactor is shown in FIG. 1 as one example of the thermal CVD apparatus which is available in the present invention, the present invention is not limited to this. That is, any other appropriate type of CVD furnace or reactor such as, for example, a hot wall CVD furnace or reactor can be used.

FIG. 2 is a view showing a comparison between the deposition delay times when Ru films are deposited on a underlayer film (SiO₂) by using a Ru(EtCp)₂ gas and a Ru(OD)₃ gas, respectively. From this figure, it can be seen that in cases where depositions were carried out by using the Ru(OD)₃ gas, there was no deposition delay time at any of the deposition temperatures of 280° C., 300° C. and 320° C., and hence the deposition times at the respective temperatures were all shortened. In contrast to this, in cases where depositions were carried out by using the Ru(EtCp)₂ gas, there were long deposition delay times at the deposition temperatures of 310° C., 330° C. and 305° C., respectively, and hence it is understood that the film thickness distribution over the surface of the substrate is liable to non-uniform and the deposition times become longer, too.

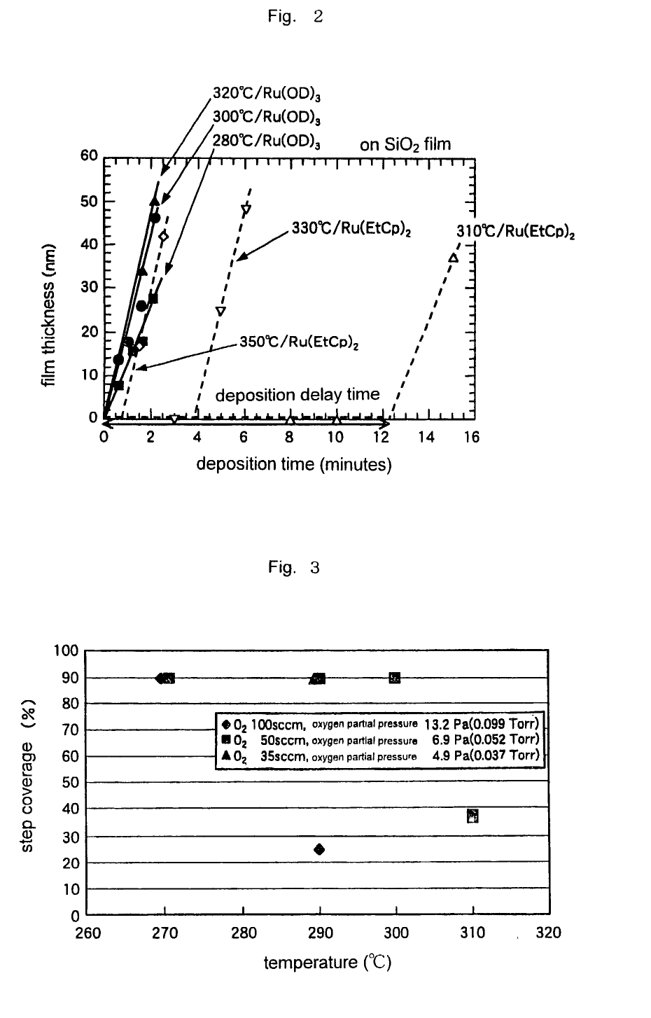

FIG. 3 is a view explaining the relation between the flow rate of an oxygen gas, the partial pressure of oxygen, the deposition temperature and the step coverage. Specifically, a hole of an aspect ratio (1:4) (a diameter of 0.25 μm) was prepared in a substrate, and films were deposited on a surface of the hole under the following conditions, and step coverage was then examined. That is, the pressure in the reaction chamber was 133 Pa (1 Torr); the partial pressure of oxygen was 4.9-13.2 Pa (0.037-0.099 Torr); the flow rate of the oxygen gas was as 35-100 sccm; and the flow rate of Ru(OD)₃ was 1 ccm. Also, deposition temperature was 270-310° C. From FIG. 3, it is understood that the lower the deposition temperature as well as the flow rate of the oxygen gas and hence the partial pressure of oxygen, the more excellent does step coverage become. Also, it is seen that the condition providing a step coverage of 80% or more is that the deposition temperature is lower than 310° C. (preferably 305° C. or lower) when the flow rate of the oxygen gas is 50 sccm or lower, i.e., when the partial pressure of oxygen is 6.9 Pa or lower. In addition, it is found that the condition providing a step coverage of 90% or more is that the deposition temperature is 300° C. or lower when the flow rate of the oxygen gas is 50 sccm or less, i.e., when the partial pressure of oxygen is 6.9 Pa or lower. Moreover, it is also understood from the result of the deposition temperature of 290° C. that the step coverage becomes 90% or more when the flow rate of the oxygen gas is less than 100 sccm (i.e., the partial pressure of oxygen is lower than 13.2 Pa), and preferably when the flow rate of the oxygen gas is 50 sccm or less (i.e., the partial pressure of oxygen is 6.9 Pa or lower). Thus, it is concluded that even at the same deposition temperature, excellent step coverage can be obtained by properly determining the flow rate of the oxygen gas or the partial pressure of oxygen. Here, note that in case of using Ru(OD)3, deposition can be done from a deposition temperature of 250° C., but no deposition can be performed at temperatures lower than 250° C. From the above discussions, it is seen that when Ru films are deposited by using Ru(OD)₃, the step coverage can be controlled to be 80% or more if the deposition temperature is in the range of 250° C. to 305° C. and if the partial pressure of oxygen is 6.9 Pa or lower. In addition, it is also seen that if the deposition temperature is in the range of 250° C. to 300° C. and if the partial pressure of oxygen is 6.9 Pa or lower, the step coverage can be made 90% or more.

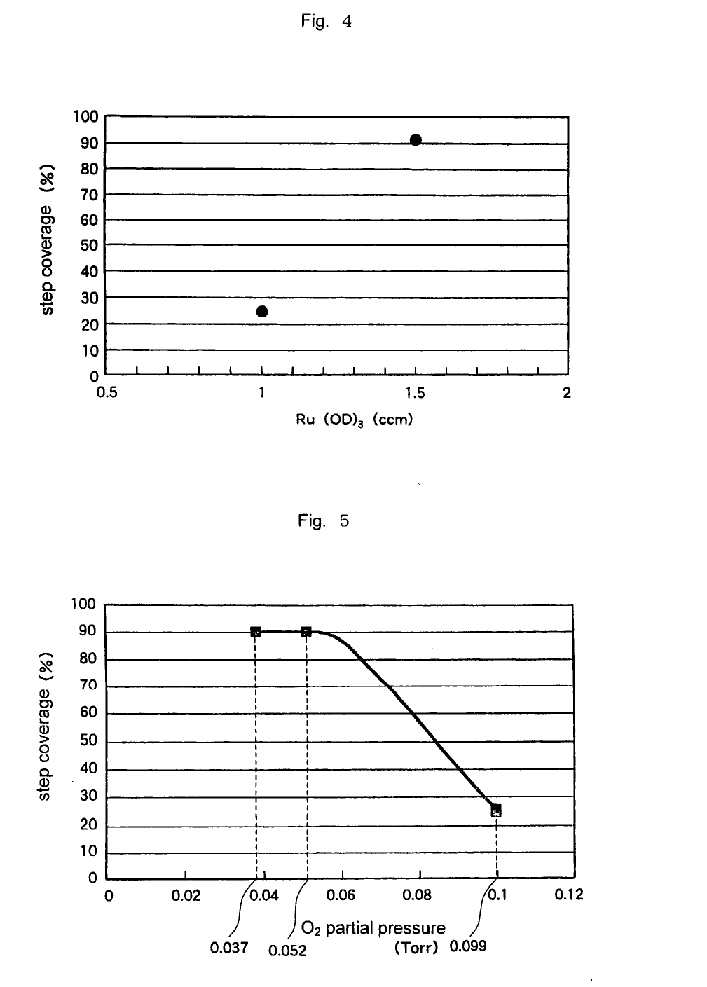

FIG. 4 is a view which explains the relation between the flow rate of a Ru(OD)₃ gas and the step coverage. Specifically, a hole of an aspect ratio (1:4) (a diameter of 0.25 μm) was prepared in a substrate, and films were deposited on a surface of the hole under the following conditions, and step coverage was then examined. That is, the temperature in the reaction chamber was 290° C.; the pressure in the reaction chamber was 133 Pa (1 Torr); the flow rate of the oxygen gas was 100 sccm; and the flow rate of Ru(OD)₃ was in the range of 1 ccm-1.5 ccm. From FIG. 4, it is found that in order to provide excellent step coverage, it is desirable to increase the flow rate of Ru(OD)₃.

FIG. 5 is a view which explains the relation between the partial pressure of oxygen and the step coverage. Specifically, a hole of an aspect ratio (1:4) (a diameter of 0.25 μm) was prepared in a substrate, and films were deposited on a surface of the hole under the following conditions, and step coverage was then examined. That is, the pressure in the reaction chamber was 133 Pa (1 Torr); the partial pressure of oxygen was 4.9-13.2 Pa (0.037-0.099 Torr); the flow rate of the oxygen gas was 35-100 sccm; and the flow rate of Ru(OD)₃ was 1 ccm. Also, the deposition temperature was 290° C. From FIG. 5, it was found that the condition providing a step coverage of 80% or more at a deposition temperature of 290° C. or lower is that the partial pressure of oxygen is 8.6 Pa (0.065 Torr) or lower, and the condition providing a step coverage of 90% or more at a deposition temperature of 290° C. or lower is that the partial pressure of oxygen is 6.9 Pa (0.052 Torr).

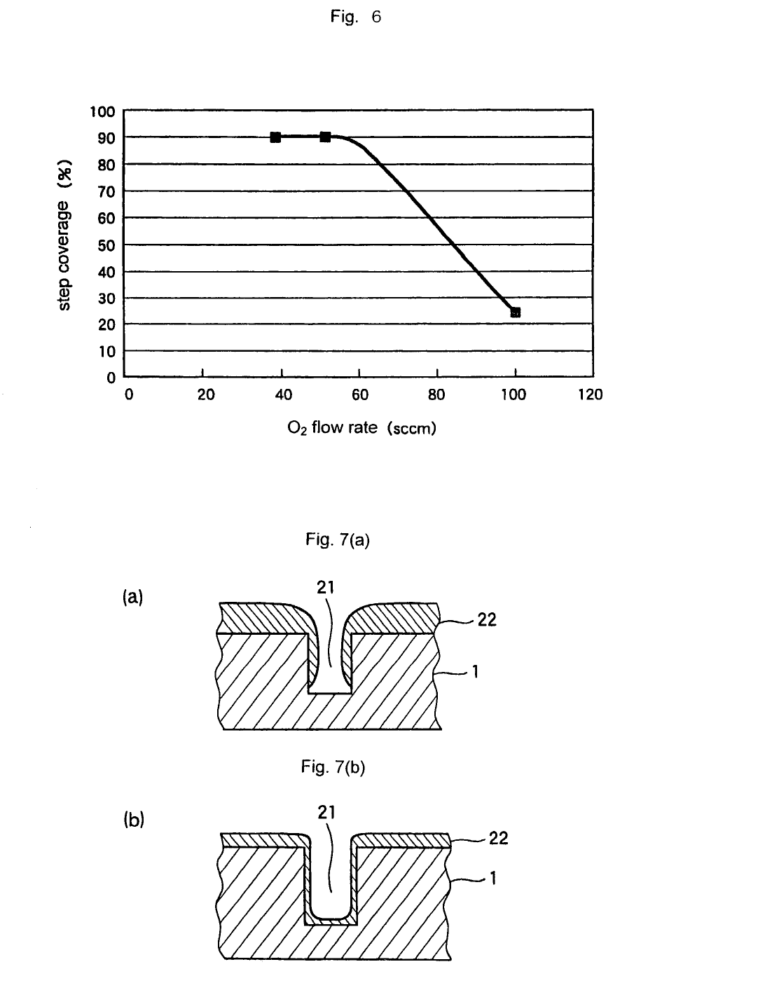

FIG. 6 is a view which explains the relation between the flow rate of the oxygen gas and the step coverage. Specifically, a hole of an aspect ratio (1:4) (a diameter of 0.25 μm) was prepared in a substrate, and films were deposited on a surface of the hole under the following conditions, and step coverage was then examined. That is, the pressure in the reaction chamber was 133 Pa (1 Torr); and the flow rate of the oxygen gas was 30-100 sccm. Also, the deposition temperature was 290° C. From FIG. 6, it is found that the condition providing a step coverage of 80% or more at a deposition temperature of 290° C. or lower is that the flow rate of the oxygen gas is 65 sccm or less, and the condition providing a step coverage of 90% or more at a deposition temperature of 290° C. or lower is that the flow rate of the oxygen gas is 50 sccm or less.

It is thought the reason why the step coverage becomes excellent in the above cases is as follows.

FIGS. 7(a) and 7(b) are cross sectional views which explain the different states of the Ru films deposited on the surface of a hole prepared in a substrate. As shown in FIG. 7(a), when the deposition temperature is high, or when the flow rate of the oxygen gas is large, that is, when the partial pressure of oxygen is high, the deposition rate becomes high, and hence the adhering probability of the films deposited also becomes high. Accordingly, a greater amount of films are deposited in the vicinity of the top or inlet of the hole 21 in the substrate 1 whereas a smaller amount of films 22 are deposited on the bottom of the hole 21.

On the contrary, when the deposition temperature is low, or when the flow rate of the oxygen gas is small, that is, when the partial pressure of oxygen is low, the deposition rate becomes low, and hence the adhering probability of the films deposited also becomes low. Thus, as shown in FIG. 7(b), the amount of the films 22 deposited in the vicinity of the inlet of the hole 21 in the substrate 1 is reduced so that an increased amount of the films can be deposited even at the bottom of the hole 21.

In addition, the reason why the deposition delay disappears with the use of Ru(OD)3 is thought as follows. That is, the Ru films adhere easily when oxygen is adsorbed, and the oxygen contained in the Ru(OD)₃ gas contributes to the initial adsorption of oxygen.

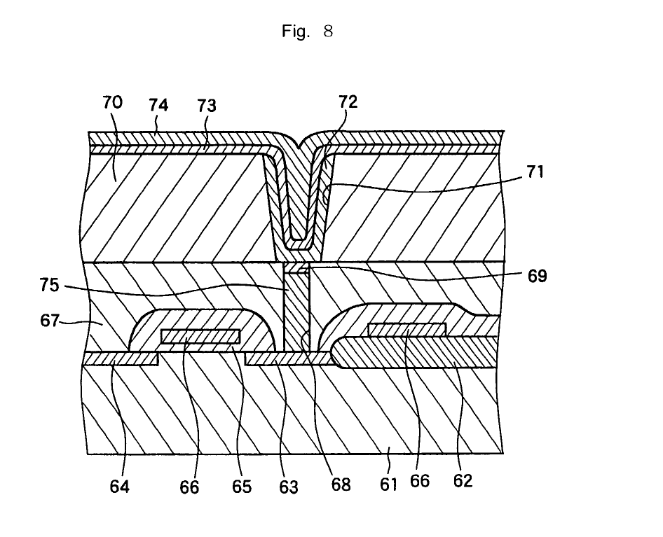

FIG. 8 is a cross sectional view which shows a part of a DRAM including Ru films formed by using the manufacturing process of the present invention.

As shown in FIG. 8, on a surface of a silicon substrate 61, there are formed field oxide films 62 for forming a multitude of transistor-forming regions in a mutually separated manner. Also, on the surface of the silicon substrate 61, there are formed source electrodes 63 and drain electrodes 64 with gate electrodes 66 acting as word lines being disposed therebetween via gate insulation films 65, respectively, on which a first interlayer insulation film 67 is provided. Contact holes 68 are formed through the first interlayer insulation film 67, and a barrier metal 69 and a plug electrode 75 connected to a corresponding one of the source electrodes 63 are formed in each of the contact holes 68. On the first interlayer insulation film 67, there is formed a second interlayer insulation film 70 through which contact holes 71 are formed. On the second interlayer insulation film 70 and in the contact holes 71, there is provided a capacitive lower electrode 72 which is made of ruthenium and connected with the barrier metals 69. Formed on the capacitive lower electrode 72 is a capacitance insulation film 73 made of Ta₂O₅ on which is formed a capacitance upper electrode 74 made of ruthenium, titanium nitride or the like. That is, with this DRAM, a capacitor cell is connected with the source electrode 63 of a MOS transistor.

Next, reference will be had to a method of manufacturing the DRAM illustrated in FIG. 8. First, a field oxide film 62 is formed in the surroundings of each transistor-forming region on the surface of the silicon substrate 61 by means of a LOCOS process. Subsequently, a gate electrode 66 is formed in each transistor-forming region through a corresponding gate insulation layer 65. Thereafter, impurities are introduced into the surface of the silicon substrate 61 by ion-implantation using the field oxide film 62 and the gate electrode 66 as masks, thus forming the source electrode 63 and the drain electrode 64 in a self-aligned manner. After each gate electrode 66 is covered with an insulating film, the first interlayer insulation film 67 is formed on the substrate 61. Then, each contact hole 68 through which a corresponding source electrode 63 is exposed is formed through the first interlayer insulation film 67, and the plug electrode 75 and the barrier metal 79 are formed in each contact hole 68. Subsequently, the second interlayer insulation film 70 is formed on the first interlayer insulation film 67, and the contact holes 71 are formed through the interlayer insulation film 70 so as to expose the corresponding barrier metals 69, respectively. Thereafter, a ruthenium film is deposited on the interlayer insulation film 70 and in the contact holes 71 by means of the semiconductor manufacturing method of the present invention, and patterning of the ruthenium film is effected to provide the capacitive lower electrode 72. The capacitance insulation film 73 made of Ta₂O₅ is then formed on the capacitive lower electrode 72, and the capacitance upper electrode 74 made of ruthenium is in turn formed on the capacitance insulation film 73 according to the manufacturing method of the present invention.

It is to be noted that the method of the present invention can be suitably applied to a substrate processing method which is intended to deposit Ru films on a substrate with good step coverage, a reduced deposition delay time and hence good in-plane uniformity.

According to the present invention, there are provided a method for manufacturing a semiconductor device and a method for processing a substrate in which films containing Ru can be easily fabricated with good step coverage, a reduced deposition delay time and hence good in-plane uniformity.

While the invention has been described in terms of preferred embodiments, those skilled in the art will recognize that the invention can be practiced with modifications within the spirit and scope of the appended claims.

What is claimed is:

1. A method for manufacturing a semiconductor device in which films containing Ru are deposited on a substrate by using a gas vaporized from Ru[CH₃COCHCO(CH₂)₃CH₃]₃ and an oxygen-containing gas at a deposition temperature of 250° C. to 305° C. and at a partial pressure of the oxygen-containing gas of 6.9 Pa or less.

2. A method for processing a substrate in which films containing Ru are deposited on the substrate by using a gas vaporized from Ru[CH₃COCHCO(CH₂)₃CH₃]₃ and an oxygen-containing gas at a deposition temperature of 250° C. to 305° C. and at a partial pressure of the oxygen-containing gas of 6.9 Pa or less.

3. A method for manufacturing a semiconductor device in which films containing Ru are deposited on a silicon-based insulation film, a barrier metal or a capacitive insulation film by using a gas vaporized from Ru[CH₃COCHCO(CH₂)₃CH₃]₃.
